(19) United States
(12) Patent Application Publication
(10) Pub. No.: US 2017/0317222 A1
(43) Pub. Date: Nov. 2, 2017

(54) SOLAR CELL MODULE

(71) Applicant: MITSUI CHEMICALS TOHCELLO, INC., Chiyoda-ku, Tokyo (JP)

(72) Inventors: Takanobu MUROFUSHI, Hitachinaka-shi (JP); Jun TOKUHIRO, Shinagawa-ku (JP)

(73) Assignee: MITSUI CHEMICALS TOHCELLO, INC., Chiyoda-ku, Tokyo (JP)

(21) Appl. No.: 15/529,573

(22) PCT Filed: Nov. 18, 2015
(86) PCT No.: PCT/JP2015/082444

§ 371 Date: May 25, 2017

(30) Foreign Application Priority Data
Nov. 28, 2014 (JP) 2014-241319

(51) Int. Cl. H01L 31/048; C08J 5/18; C09K 3/10; C08K 5/00

(52) U.S. Cl. CPC H01L 31/0481; C08K 5/005; C08K 5/0008; C09K 3/10; C08J 5/18; C08J 2323/08; C09K 2200/062

(57) ABSTRACT

Disclosed is a solar cell module including an n-type crystalline silicon-based solar cell element as a power generation element, in which at least one surface of the n-type crystalline silicon-based solar cell element is encapsulated with a solar-cell encapsulating material including an ethylene•α-olefin copolymer satisfying the following requirements a1) to a4).

a1) A content proportion of a structural unit derived from ethylene is in a range of 80 to 90 mol %, and a content proportion of a structural unit derived from an α-olefin having 3 to 20 carbon atoms is in a range of 10 to 20 mol %.

a2) MFR measured under defined conditions is in a range of 0.1 to 50 g/10 minutes.
a3) A density, which is measured under defined conditions in a range of 0.865 to 0.884 g/cm³.

a4) A Shore A hardness, which is measured under defined conditions is in a range of 60 to 85.

### TECHNICAL FIELD

The present invention relates to a solar cell module.

### BACKGROUND ART

Global environmental problems, energy problems, and the like become more serious, and thus a solar cell attracts attention as energy generation means that is clean and has no concern about exhaustion. In a case where a solar cell is used outside, for example, in the roof of a building, the solar cell is generally used in a form of solar cell modules.

Generally, a solar cell module is manufactured through the following procedure. Firstly, a crystalline solar cell element (which may be described below as a power generation element or a cell, but both expressions indicate the same element), a thin-film solar cell element, or the like is manufactured. The crystalline solar cell element is formed of polycrystalline silicon, single crystal silicon, and the like. The thin-film solar cell element is obtained by forming a very thin film of several μm on a substrate such as glass, using amorphous silicon or crystalline silicon.

Then, in order to obtain a crystalline solar cell module, a protective sheet for a solar cell module (front surface side transparent protection member), a solar-cell encapsulating material sheet, a crystalline solar cell element, a solar-cell encapsulating material sheet, and a protective sheet for a solar cell module (back surface side protection member) are stacked in this order.

In order to obtain a thin-film type solar cell module, a thin-film solar cell element, a solar-cell encapsulating material sheet, and a protective sheet for a solar cell module (member for protecting a back surface side) are stacked in this order. Then, a solar cell module is manufactured by using a lamination method in which vacuum aspiration is performed on the above components, and thermal press bonding is performed.

The solar cell module manufactured in this manner is weather resistant, and is suitable for being used outside, for example, in the roof of a building.

An ethylene-vinyl acetate copolymer (EVA) film as a solar-cell encapsulating material is excellent in transparency, flexibility, adhesiveness, and the like, and thus is widely used. For example, Patent Document 1 discloses an encapsulating film which is formed of an EVA composition containing a cross-linking agent and trimellitic acid ester, and is excellent in both of adhesiveness and film forming properties. However, in a case where an EVA composition is used as a constituent material of a solar-cell encapsulating material, there is a concern of a possibility that a component such as acetic acid gas which is generated due to the decomposition of EVA may affect the solar cell element.

In contrast, using a polyolefin-based material, particularly, an ethylene-based material as an encapsulating film material also has been proposed from a viewpoint of excellent insulating properties (for example, see Patent Document 2).

A resin composition for the solar-cell encapsulating material which uses an ethylene•αolefin copolymer has been also proposed (for example, see Patent Document 3). The ethylene•αolefin copolymer has excellent balance between rigidity and cross-linking characteristics and excellent extrusion moldability.

### RELATED DOCUMENT

### Patent Document

[Patent Document 1] Japanese Laid-open Patent Publication No. 2010-53298

[Patent Document 2] Japanese Laid-open Patent Publication No. 2006-210906

[Patent Document 3] Japanese Laid-open Patent Publication No. 2010-258439

### SUMMARY OF THE INVENTION

However, according to studies by the present inventors, a polyolefin-based composition had a difficulty in satisfying various characteristics such as transparency, blocking resistance, and moldability during extrusion at the same time. The polyolefin-based copolymer described in Patent Document 2 has a problem of insufficient cross-linking characteristics or the intensification of distortion caused by cross-linking, and thus there is a possibility that a glass substrate deforms or breaks. A resin composition for a solar-cell encapsulating material made of an ethylene•αolefin copolymer, which is described in Patent Document 3, has insufficient balance between electrical characteristics and cross-linking characteristics.

In response to the recent distribution of photovoltaic power generation, an increase in the size of a power generation system such as mega solar is underway, and there is an attempt to increase the system voltage in order to decrease transmission loss. When the system voltage increases, the potential difference increases between the frame and the cell in the solar cell module. That is, the frame in the solar cell module is generally grounded, and, when the system voltage of a solar cell array reaches 600 V to 1,000 V, the potential difference between the frame and the cell reaches 600 V to 1,000 V which is the system voltage in a module in which the voltage becomes highest, and power generation during daylight is maintained in a state where a high voltage is applied.

Glass has a lower electric resistance than an encapsulating material, and a high voltage is generated between the glass and the cell through the frame. That is, in a state of power generation during daylight, the potential difference between the cell and the module and between the cell and the glass surface gradually increases from the ground side in modules connected in a series, and, in a place in which the potential difference is greatest, a potential difference almost as high as the system voltage is maintained.

Among solar cell modules used in the above state, examples of a module for which a crystalline power generation element in which a potential induced degradation (PID) phenomenon occurs is used are also reported. In the PID phenomenon, the output is significantly decreased, and characteristic deterioration occurs.

Considering the above circumstances, the present invention is to provide a solar cell module which includes an n-type crystalline silicon-based solar cell element and has excellent PID resistance. In the n-type crystalline silicon-based solar cell element, an n-type semiconductor is used as a substrate, and a p-type semiconductor layer is formed on the substrate.

According to the studies by the present inventors, in an n-type crystalline silicon-based solar cell module, PID occurs more easily than in a p-type crystalline silicon-based solar cell module, and there is a case where PID occurs even when a polyolefin-based solar-cell encapsulating material is used.

The present inventors performed intensive studies in order to achieve the above-described object, and consequently found that, when a specific ethylene•α-olefin copolymer in which the content proportion, density, MFR, and Shore A hardness of an ethylene unit satisfy predetermined requirements is used, a solar-cell encapsulating material having excellent balance among various characteristics such as transparency, adhesiveness, heat resistance, flexibility, appearance, cross-linking characteristics, electrical characteristics, and extrusion moldability can be obtained, and a solar cell module which includes an n-type crystalline silicon-based solar cell element as a power generation cell and for which the solar-cell encapsulating material is used has very excellent PID resistance. The present inventors found that, when the content of an aluminum element satisfies a specific range, cross-linking characteristics and electrical characteristics are superior and completed the present invention.

The present inventors found that, when a solar-cell encapsulating material having a volume intrinsic resistance measured based on JIS K6911 in a specific range and various material properties described above is used, it is possible to suppress a decrease in the output of the solar cell module even when a state where a high voltage is applied between the frame and the cell in the solar cell module is maintained, and it is possible to significantly suppress the occurrence of PID and completed the present invention.

That is, according to the present invention, a solar cell module which is described in the following description is provided.

[1] A solar cell module including: an n-type crystalline silicon-based solar cell element as a power generation element, in which at least one surface of the n-type crystalline silicon-based solar cell element is encapsulated with a solar-cell encapsulating material including an ethylene•α-olefin copolymer satisfying the following requirements a1) to a4).

a1) A content proportion of a structural unit derived from ethylene is in a range of 80 to 90 mol %, and a content proportion of a structural unit derived from an α-olefin having 3 to 20 carbon atoms is in a range of 10 to 20 mol %.

a2) MFR, which is on the basis of ASTM D1238 and is measured under conditions of 190° C. and a load of 2.16 kg, is in a range of 0.1 to 50 g/10 minutes.

a3) A density, which is measured on the basis of ASTM D1505, is in a range of 0.865 to 0.884 g/cm³.

a4) A Shore A hardness, which is measured on the basis of ASTM D2240, is in a range of 60 to 85.

[2] The solar cell module according to [1], in which the solar-cell encapsulating material further satisfies the following requirement a5).

a5) A volume intrinsic resistance, which is on the basis of JIS K6911 and is measured at a temperature of 100° C. and an applied voltage of 500 V, is in a range of 1.0×10¹³ to 1.0×10¹⁸ Ω·cm.

[3] The solar cell module according to [1], in which the ethylene•α-olefin copolymer further satisfies the following requirement a6). a6) A content of an aluminum element in the ethylene•α-olefin copolymer is 10 to 500 ppm.

[4] The solar cell module according to [2], in which the ethylene•α-olefin copolymer further satisfies the following requirement a6).

a6) A content of an aluminum element in the ethylene•α-olefin copolymer is 10 to 500 ppm.

[5] The solar cell module according to any one of [1] to [4], in which the MFR of the ethylene•α-olefin copolymer which is on the basis of ASTM D1238 and is measured under conditions of 190° C. and a load of 2.16 kg is 2 to 27 g/10 minutes.

[6] The solar cell module according to any one of [1] to [5] , in which the solar-cell encapsulating material further includes 0.005 to 5.0 parts by mass of an organic peroxide having a one-minute half-life temperature in a range of 100° C. to 170° C. with respect to 100 parts by mass of the ethylene•αolefin copolymer.

[7] The solar cell module according to any one of [1] to [6] , in which the ethylene•α-olefin copolymer is a copolymer polymerized in the presence of a catalyst for olefin polymerization which is made up of a metallocene compound and at least one type of compound selected from the group consisting of organic aluminum oxy compounds and organic aluminum compounds.

[8] The solar cell module according to any one of [1] to [7] , in which the solar-cell encapsulating material is made of an ethylene-based resin composition including 0.1 to 5 parts by mass of a silane coupling agent and 0.1 to 3 parts by mass of a cross-linking agent with respect to 100 parts by mass of the ethylene•αolefin copolymer.

[9] The solar cell module according to [8] , in which the ethylene-based resin composition included in the solar-cell encapsulating material further includes 0.005 to 5 parts by mass of at least one type selected from the group consisting of an ultraviolet absorbing agent, a heat-resistance stabilizer, and a light stabilizer with respect to 100 parts by mass of the ethylene•α-olefin copolymer.

[10] The solar cell module according to [8] or [9] , in which the ethylene-based resin composition included in the solar-cell encapsulating material further includes 0.05 to 5 parts by mass of a cross-linking assistant with respect to 100 parts by mass of the ethylene•α-olefin copolymer.

[11] The solar cell module according to any one of [1] to [10], in which the solar-cell encapsulating material is a material obtained by dissolving and kneading the ethylene•α-olefin copolymer and an additive and then extruding the ethylene•α-olefin copolymer and the additive in a sheet shape.

[12] The solar cell module according to any one of [1] to [11], in which the solar-cell encapsulating material has a sheet shape.

[13] The solar cell module according to any one of [1] to [12], further including:

a front surface side transparent protection member;

a back surface side protection member; and

an encapsulating layer which is formed by cross-linking the solar-cell encapsulating material and encapsulates the n-type crystalline silicon-based solar cell element between the front surface side transparent protection member and the back surface side protection member.

According to the present invention, it is possible to provide an n-type crystalline silicon-based solar cell module capable of significantly suppressing the occurrence of the PID phenomenon even when a state where a high voltage is applied between the frame and the cell is maintained.

### BRIEF DESCRIPTION OF THE DRAWINGS

The object and other objects, features and advantages which are described above are clarified by a desired embodiment which will be described below, and the following accompanying drawings.

FIG. 1 is a schematic cross-sectional view illustrating an embodiment of an n-type crystalline silicon-based solar cell module according to the present invention.

FIG. 2 is a schematic plan view illustrating one configuration example of a light-receiving surface and a back surface of a solar cell element.

### DESCRIPTION OF EMBODIMENTS

Hereinafter, an embodiment according to the present invention will be described with reference to the drawings. In all of the drawings, similar components are denoted by the similar reference numerals and descriptions thereof will be not repeated. “to” in a numerical range means being equal to or greater than and equal to or smaller than as long as there is no particular statement about “to”.

1. Regarding Solar-Cell Encapsulating Material

A solar-cell encapsulating material of the embodiment includes an ethylene•α-olefin copolymer satisfying at least the following requirements a1) to a4).

(Ethylene•α-olefin Copolymer)

The ethylene•α-olefin copolymer which is used in the solar-cell encapsulating material of the embodiment can be obtained by copolymerizing ethylene and an α-olefin having 3 to 20 carbon atoms.

As an α-olefin, generally, one type of α-olefin having 3 to 20 carbon atoms may be singly used or a combination of two or more types may be used. Among these materials, an α-olefin having 10 or less carbon atoms is preferable, and an α-olefin having 3 to 8 carbon atoms is particularly preferable. Specific examples of such α-olefin may include propylene, 1-butene, 1-pentene, 1-hexene, 3-methyl-1-butene, 3,3-dimethyl-1-butene, 4-methyl-1-pentene, 1-octene, 1-decene, and 1-dodecene. Among these materials, from a viewpoint of easy acquisition, one or more types selected from propylene, 1-butene, 1-pentene, 1-hexene, 4-methyl-1-pentene, and 1-octene are preferable. The ethylene•α-olefin copolymer maybe a random copolymer or a block copolymer. However, from a viewpoint of flexibility, the random copolymer is preferable.

Hereinafter, the requirements a1) to a4) will be described.

(Requirement a1)

The content proportion of a structural unit derived from ethylene, which is contained in the ethylene•α-olefin copolymer, is in a range of 80 to 90 mol %, preferably in a range of 80 to 88 mol %, more preferably in a range of 82 to 88 mol %, and particularly preferably in a range of 82 to 87 mol %.

The ratio of a structural unit, which is contained in the ethylene•αolefin copolymer and is derived from an α-olefin having 3 to 20 carbon atoms (hereinafter, also referred to as “α-olefin unit”), is in a range of 10 to 20 mol %, preferably in a range of 12 to 20 mol %, more preferably in a range of 12 to 18 mol %, and still more preferably in a range of 13 to 18 mol %.

When the content proportion of the α-olefin unit contained in the ethylene•αolefin copolymer is equal to or greater than the lower limit value, high transparency can be obtained. In addition, it is possible to easily perform extrusion molding at a low temperature, and, for example, extrusion molding at 130° C. or less is possible. Thus, even in a case where an organic peroxide is kneaded into the ethylene•αolefin copolymer, it is possible to suppress the progress of a cross-linking reaction in an extruder, and it is possible to prevent the generation of a gelatinous foreign substance in the solar-cell encapsulating material sheet and the deterioration of the appearance of the sheet. In addition, appropriate flexibility is obtained, and thus it is possible to prevent the occurrence of the cracking of a solar cell element, the chipping of a thin-film electrode, or the like during the lamination molding of a solar cell module.

When the content proportion of the α-olefin unit contained in the ethylene•αolefin copolymer is equal to or smaller than the upper limit value, the crystallization rate of the ethylene•αolefin copolymer becomes appropriate, and thus the sheet pressed out from the extruder is not sticky, peeling from a cooling roll is easy, and it is possible to efficiently obtain a sheet-shape solar-cell encapsulating material. In addition, the sheet is not sticky, blocking can be prevented, and the extruding properties of the sheet become favorable. In addition, it is also possible to prevent the degradation of heat resistance.

(Requirement a2)

The melt flow rate (MFR) of the ethylene•αolefin copolymer, which is on the basis of ASTM D1238 and measured under conditions of 190° C. and a load of 2.16 kg, is in a range of 0.1 to 50 g/10 minutes, preferably in a range of 2 to 50 g/10 minutes, more preferably in a range of 10 to 50 g/10 minutes, still more preferably in a range of 10 to 40 g/10 minutes, particularly preferably in a range of 12 to 27 g/10 minutes, and most preferably in a range of 15 to 25 g/10 minutes. The MFR of the ethylene•αolefin copolymer can be adjusted by adjusting the polymerization temperature and the polymerization pressure during a polymerization reaction described below, the molar ratio between the monomer concentration and the hydrogen concentration in ethylene and the α-olefin in a polymerization system, and the like.

(Calender Molding)

When the MFR is equal to or greater than 0.1 g/10 minutes and smaller than 10 g/10 minutes, it is possible to manufacture the sheet through calender molding. When the MFR is equal to or greater than 0.1 g/10 minutes and smaller than 10 g/10 minutes, the fluidity of the resin composition containing the ethylene•αolefin copolymer is low, and thus it is possible to prevent a laminating device from being contaminated by the molten resin extracted when the sheet is laminated together with the cell element, which is preferable.

(Extrusion Molding)

When the MFR is equal to or greater than 2 g/10 minutes, and is preferably equal to or greater than 10 g/10 minutes, the fluidity of the resin composition containing the ethylene•α-olefin copolymer is improved, and it is possible to improve the productivity during sheet extrusion molding.

When the MFR is set to equal to or smaller than 50 g/10 minutes, the molecular weight is increased so that it is possible to suppress the adhesion to a roller surface of a chilled roller or the like, and thus peeling is not required, and a sheet having a uniform thickness can be molded. Since the resin composition becomes “stiff”, it is possible to easily mold a sheet having a thickness of equal to or greater than 0.1 mm. In addition, since the cross-linking characteristics are improved during the lamination molding of the solar cell module, the cross-linkable resin is sufficiently cross-linked so that the degradation of the heat resistance can be suppressed.

When the MFR is equal to or smaller than 27 g/10 minutes, it is possible to suppress drawdown during the sheet molding, to mold a sheet having a wide width, to further improve the cross-linking characteristics and the heat resistance, and to obtain the most favorable solar-cell encapsulating material sheet.

Meanwhile, in a case where the cross-linking treatment of the resin composition is not performed in the laminate process of the solar cell module described below, the decomposition of the organic peroxide in the melt extrusion step has only a small effect, and thus it is also possible to obtain a sheet through extrusion molding by using a resin composition having a MFR of equal to or greater than 0.1 g/10 minutes and smaller than 10 g/10 minutes, and preferably equal to or greater than 0.5 g/10 minutes and smaller than 8.5 g/10 minutes. In a case where the content of the organic peroxide in the resin composition is equal to or smaller than 0.15 parts by mass, it is also possible to manufacture a sheet through extrusion molding at a molding temperature in a range of 170° C. to 250° C. by using a resin composition having a MFR of equal to or greater than 0.1 g/10 minutes and smaller than 10 g/10 minutes while performing a silane modification treatment or a fine cross-linking treatment. When the MFR is in the above-described range, it is possible to prevent the laminating device from being contaminated by a molten resin extracted when the sheet is laminated together with the solar cell element, which is preferable.

(Requirement a3)

The density of the ethylene•α-olefin copolymer, which is measured based on ASTM D1505, is 0.865 to 0.884 g/cm³, preferably 0.866 to 0.883 g/cm³, more preferably 0.866 to 0.880 g/cm³, and further preferably 0.867 to 0.880 g/cm³. The density of the ethylene•αolefin copolymer may be adjusted in accordance with balance between a content proportion of an ethylene unit and a content proportion of an α-olefin unit. That is, when the content proportion of the ethylene unit is increased, crystallinity is improved, and thus an ethylene•α-olefin copolymer having high density may be obtained. When the content proportion of the ethylene unit is decreased, the crystallinity is lowered, and thus an ethylene•α-olefin copolymer having low density may be obtained.

When the density of the ethylene•α-olefin copolymer is equal to or smaller than the upper limit value, the crystallinity becomes low, and it is possible to enhance transparency. Extrusion molding at a low temperature becomes possible, and, for example, it is possible to perform extrusion molding at 130° C. or less. Thus, even in a case where an organic peroxide is kneaded into the ethylene•α-olefin copolymer, it is possible to suppress the progress of a cross-linking reaction in an extruder, and it is possible to prevent the generation of a gel-shaped foreign substance in the solar-cell encapsulating material sheet and the deterioration of the appearance of the sheet. In addition, appropriate flexibility is obtained, and thus it is possible to prevent the occurrence of the cracking of a solar cell element, the chipping of a thin-film electrode, or the like during the lamination molding of a solar cell module.

When the density of the ethylene•α-olefin copolymer is equal to or greater than the lower limit value, the crystallization rate of the ethylene•α-olefin copolymer becomes appropriate, and thus the sheet pressed out from the extruder is not sticky, peeling from a cooling roll is easy, and it is possible to efficiently obtain a solar-cell encapsulating material sheet. In addition, the sheet is not sticky, blocking can be prevented, and the extruding properties of the sheet become favorable. In addition, since the ethylene•α-olefin copolymer is sufficiently cross-linked, it is also possible to prevent the degradation of heat resistance.

(Requirement a4)

The Shore A hardness of the ethylene•α-olefin copolymer, which is measured on the basis of ASTM D2240, is in a range of 60 to 85, preferably in a range of 62 to 83, more preferably in a range of 62 to 80, and still more preferably in a range of 65 to 80. The Shore A hardness of the ethylene•α-olefin copolymer can be adjusted by controlling the content proportion or density of the ethylene unit in the ethylene•α-olefin copolymer within a numeric range described below. That is, the Shore A hardness becomes great in the ethylene•α-olefin copolymer having a high content proportion of the ethylene unit and a high density. On the other hand, the Shore A hardness becomes low in the ethylene •α-olefin copolymer having a low content proportion of the ethylene unit and a low density. Meanwhile, the Shore A hardness is measured after a load is applied to a test specimen sheet, and then 15 seconds or more elapses.

When the Shore A hardness is equal to or greater than the lower limit value, the crystallization rate of the ethylene•α-olefin copolymer becomes appropriate, and thus the sheet pressed out from the extruder is not sticky, peeling from a cooling roll is easy, and it is possible to efficiently obtain a solar-cell encapsulating sheet. In addition, the sheet is not sticky, blocking can be prevented, and the extruding properties of the sheet become favorable. In addition, it is also possible to prevent the degradation of heat resistance.

When the Shore A hardness is equal to or smaller than the upper limit value, high transparency can be obtained. In addition, it is possible to easily perform extrusion molding at a low temperature, and, for example, extrusion molding at 130° C. or less is possible. Thus, even in a case where an organic peroxide is kneaded into the ethylene•α-olefin copolymer, it is possible to suppress the progress of a cross-linking reaction in an extruder, and it is possible to improve the appearance of the solar-cell encapsulating sheet. In addition, appropriate flexibility is obtained, and thus it is possible to prevent the occurrence of the cracking of a solar cell element, the chipping of a thin-film electrode, or the like during the lamination molding of a solar cell module.

In addition, the solar-cell encapsulating material of the embodiment preferably further satisfies the following requirements a5) and a6).

(Requirement a5)

In the solar-cell encapsulating material of the embodiment, the volume intrinsic resistance, which is on the basis of JIS K6911 and is measured at a temperature of 100° C. and an applied voltage of 500 V, is preferably in a range of 1.0×10¹³ to 1.0×10¹⁸ Ω·cm.

A solar-cell encapsulating material having a large volume intrinsic resistance tends to have a characteristic of suppressing the occurrence of the PID phenomenon. During the time period in which sunlight is radiated, in a solar cell module of the related art, the module temperature may reach, for example, 70° C. or higher, and thus there is a demand for a volume intrinsic resistance under a higher temperature condition than the volume intrinsic resistance at normal temperature (23° C.) reported in the related art from the viewpoint of long-term reliability, and a volume intrinsic resistance at a temperature of 100° C. becomes important.

The volume intrinsic resistance is preferably in a range of 1.0×10¹⁴ to 1.0×10¹⁸ Ω·cm, more preferably in a range of 5.0×10¹⁴ to 1.0×10¹⁸Ω·cm, and most preferably in a range of 1.0×10¹⁵ to 1.0×10¹⁸ Ω·cm.

When the volume intrinsic resistance is equal to or greater than the lower limit value, it is possible to suppress the occurrence of the PID phenomenon for a short period of time such as approximately one day in a constant temperature and humidity test of 85° C. and 85% rh. When the volume intrinsic resistance is equal to or smaller than the upper limit value, electrostatic electricity is not easily generated in the sheet, and thus it is possible to prevent the adsorption of trash, and it is possible to suppress the incorporation of trash into the solar cell module and the degradation of the power generation efficiency or the long-term reliability.

When the volume intrinsic resistance is equal to or greater than 5.0×10¹⁴ Ω·cm, there is a tendency that it is possible to further delay the occurrence of the PID phenomenon in a constant temperature and humidity test of 85° C. and 85% rh, which is desirable.

The volume intrinsic resistance is measured after an encapsulating material sheet is molded, and then is cross-linked in a vacuum laminator, a hot press, a cross-linking furnace, or the like and is processed into a flat sheet. In addition, for the sheet in a module stacked body, the volume intrinsic resistance is measured after removing other layers.

(Requirement a6)

The content (residual amount) of an aluminum element (hereinafter, also expressed as “Al”) contained in the ethylene•α-olefin copolymer is preferably in a range of 10 to 500 ppm, more preferably in a range of 20 to 400 ppm, and still more preferably in a range of 20 to 300 ppm.

The content of Al depends on the concentration of an organic aluminum oxy compound or an organic aluminum compound which is added in a polymerization process of the ethylene•α-olefin copolymer.

In a case where the content of Al is equal to or greater than the lower limit value, an organic aluminum oxy compound or an organic aluminum compound can be added in the polymerization process of the ethylene•α-olefin copolymer at approximately a concentration at which the activity of a metallocene compound can be sufficiently developed, and thus the addition of a compound that reacts with the metallocene compound and thus forms an ion pair becomes unnecessary. In a case where the compound that forms an ion pair is added, the compound that forms an ion pair remains in the ethylene•α-olefin copolymer, and thus the degradation of the electrical characteristics may be caused (for example, there is a tendency that the electrical characteristics at a high temperature of 100° C. or the like degrade), but the content of Al being equal to or greater than the lower limit value is capable of preventing the above-described phenomenon. In addition, in order to decrease the content of Al, a demineralization treatment in an acid or an alkali becomes necessary, and there is a tendency that an acid or an alkali remaining in the ethylene•α-olefin copolymer being obtained causes the corrosion of the electrode. The costs of the ethylene•α-olefin copolymer also increase in order to perform a demineralization treatment, but the above-described demineralization treatment becomes unnecessary.

In addition, when the content of Al is equal to or smaller than the upper limit value, it is possible to prevent the progress of a cross-linking reaction in an extruder, and thus it is possible to improve the appearance of the solar-cell encapsulating sheet.

As a method for controlling the above-described aluminum element included in the ethylene•α-olefin copolymer, it is possible to control the aluminum element included in the ethylene•α-olefin copolymer by, for example, adjusting the concentration in the manufacturing process of an organic aluminum oxy compound (II-1) or an organic aluminum compound (II-3) described in the manufacturing method of the ethylene•α-olefin copolymer described below or the polymerization activity of the metallocene compound under the manufacturing conditions of the ethylene•α-olefin copolymer.

(Melting Peak)

The differential scanning calorimetry (DSC)-based melting peak of the ethylene •α-olefin copolymer is preferably present in a range of 30° C. to 90° C., more preferably present in a range of 33° C. to 90° C., and particularly preferably present in a range of 33° C. to 88° C.

When the melting peak is equal to or smaller than the upper limit value, the crystallinity is appropriate, and the transparency is favorable. In addition, flexibility is also appropriate, and there is a tendency that it is possible to suppress the cracking of a solar cell element, the chipping of a thin-film electrode, or the like during the lamination molding of a solar cell module. When the melting peak is equal to or greater than the lower limit value, the resin composition is slightly sticky, sheet blocking can be suppressed, and the extruding properties of the sheet are favorable. In addition, cross-linking becomes sufficient, and the heat resistance is also favorable.

The solar cell module of the embodiment is preferably a solar cell module including a front surface side transparent protection member, a back surface side protection member, an n-type crystalline silicon-based solar cell element, and an encapsulating layer which is formed of the solar-cell encapsulating material and encapsulates the solar cell element between the front surface side transparent protection member and the back surface side protection member. The solar-cell encapsulating material may be cross-linked as necessary or may not be cross-linked. When the solar cell element used in the module is a crystalline power generation element, there is a possibility of the PID phenomenon being observed, and thus it is possible to particularly preferably apply the embodiment.

(Manufacturing Method of ethylene•α-olefin Copolymer)

The ethylene•α-olefin copolymer can be manufactured by using various metallocene compounds described below as a catalyst. Examples of the metallocene compounds that can be used include the metallocene compounds described in Japanese Laid-open Patent Publication No. 2006-077261, Japanese Laid-open Patent Publication No. 2008-231265, Japanese Laid-open Patent Publication No. 2005-314680 and the like. However, a metallocene compound having a different structure from those of the metallocene compounds described in the above-described patent documents may also be used, and a combination of two or more metallocene compounds may also be used.

Examples of the polymerization reaction in which the metallocene compound is used include aspects described below as preferable examples.

Ethylene and one or more types of monomers selected from α-olefins and the like are supplied in the presence of a catalyst for olefin polymerization which is made up of a well-known metallocene compound of the related art and at least one type of compound (II) (also referred to as a catalyst assistant) selected from the group consisting of an organic aluminum oxy compound (II-1), a compound which reacts with the metallocene compound (I) and thus forms an ion pair (II-2), and an organic aluminum compound (II-3).

As the organic aluminum oxy compound (II-1), the compound which reacts with the metallocene compound (I) and thus forms an ion pair (II-2), and the organic aluminum compound (II-3), it is possible to use the metallocene compounds described in Japanese Laid-open Patent Publication No. 2006-077261, Japanese Laid-open Patent Publication No. 2008-231265, Japanese Laid-open Patent Publication No. 2005-314680 and the like. However, a metallocene compound having a different structure from those of the metallocene compounds described in the above-described patent documents may also be used. The above-described compounds may be individually injected into a polymerization atmosphere or be brought into contact with each other in advance and then injected into a polymerization atmosphere. For example, the compounds may be carried by the fine particle-form inorganic oxide carrier described in Japanese Laid-open Patent Publication No. 2005-314680 or the like.

Meanwhile, it is preferable to manufacture the ethylene•α-olefin copolymer with no substantial use of the compound which reacts with the metallocene compound (I) and thus forms an ion pair (II-2), whereby the ethylene•α-olefin copolymer having excellent electrical characteristics can be obtained.

The polymerization of the ethylene•α-olefin copolymer can be performed by using any one of a well-known gas-phase polymerization method of the related art and a liquid-phase polymerization method such as a slurry polymerization method or a solution polymerization method. The polymerization is preferably performed by using the liquid-phase polymerization method such as the solution polymerization method. In a case where the ethylene•α-olefin copolymer is manufactured by performing the copolymerization of ethylene and an α-olefin having 3 to 20 carbon atoms by using the metallocene compound, the metallocene compound (I) is used in an amount in a range of, generally, 10⁻⁹ moles to 10⁻¹ moles, and preferably 10⁻⁸ moles to 10⁻² moles per a reaction volume of one liter.

The compound (II-1) is used in an amount in which the molar ratio [(II-1)/M] of the compound (II-1) to all transition metal atoms (M) in the compound (I) is generally in a range of 1 to 10000, and preferably in a range of 10 to 5000. The compound (II-2) is used in an amount in which the molar ratio [(II-2) /M] of the compound (II-2) to all the transition metal atoms (M) in the compound (I) is generally in a range of 0.5 to 50, and preferably in a range of 1 to 20. The compound (II-3) is used in an amount in a range of, generally, 0 to 5 millimoles, and preferably approximately 0 to 2 millimoles per a polymerization volume of one liter.

In the solution polymerization method, when ethylene and an α-olefin having 3 to 20 carbon atoms are copolymerized in the presence of the above-described metallocene compound, it is possible to efficiently manufacture an ethylene•αolefin copolymer having a large content of a comonomer, a narrow composition distribution and a narrow molecular weight distribution. Here, the charge molar ratio of ethylene to the α-olefin having 3 to 20 carbon atoms is generally in a range of 10:90 to 99.9:0.1, preferably in a range of 30:70 to 99.9:0.1, and more preferably in a range of 50:50 to 99.9:0.1 (ethylene:α-olefin).

Examples of the α-olefin having 3 to 20 carbon atoms include linear or branched α-olefins such as propylene, 1-butene, 2-butene, 1-pentene, 3-methyl-1-butene, 1-hexene, 4-methyl-l-pentene, 3-methyl-l-pentene, 1-octene, 1-decene, 1-dodecene, and the like. Examples of the α-olefin that can be used in the solution polymerization method also include polar group-containing olefins. Examples of the polar group-containing olefins include α,β-unsaturated carboxylic acids such as acrylic acid, methacrylic acid, fumaric acid and maleic anhydride, and metallic salts thereof such as sodium salts; α,β-unsaturated carboxylic acid esters such as methyl acrylate, ethyl acrylate, n-propyl acrylate, methyl methacrylate and ethyl methacrylate; vinyl esters such as vinyl acetate and vinyl propionate; unsaturated glycidyls such as glycidyl acrylate and glycidyl methacrylate; and the like. In addition, it is also possible to proceed with high-temperature solution polymerization in the co-presence of an aromatic vinyl compound in the reaction system. Examples of the aromatic vinyl compound include styrenes such as styrene, o-methyl styrene, m-methyl styrene, p-methyl styrene, o,p-dimethyl styrene, methoxy styrene, vinyl benzoate, vinyl methyl benzoate, vinyl benzyl acetate, hydroxy styrene, p-chloro styrene and divinyl benzene; 3-phenylpropylene, 4-phenylpropylene, α-methyl styrene, and the like. Among the above-described α-olefins, propylene, 1-butene, 1-hexene, 4-methyl-l-pentene, and 1-octene are preferably used. In addition, in the solution polymerization method, a cyclic olefin having 3 to 20 carbon atoms, for example, cyclopentene, cycloheptene, norbornene or 5-methyl-2-norbornene may be jointly used.

The “solution polymerization method” is a collective term for all methods in which polymerization is performed in a state where a polymer is dissolved in an inert hydrocarbon solvent described below. In the solution polymerization method, the polymerization temperature is generally in a range of 0° C. to 200° C., preferably in a range of 20° C. to 190° C., and more preferably in a range of 40° C. to 180° C. In the solution polymerization method, in a case where the polymerization temperature is below 0° C., the polymerization activity extremely degrades, and the removal of polymerization heat also becomes difficult, which makes the solution polymerization method impractical in terms of productivity. In addition, when the polymerization temperature exceeds 200° C., the polymerization activity extremely degrades, and thus the solution polymerization method is not practical in terms of productivity.

The polymerization pressure is generally in a range of normal pressure to 10 MPa (gauge pressure), and preferably in a range of normal pressure to 8 MPa (gauge pressure). Copolymerization can be performed in all of a batch method, a semi-continuous method, and a continuous method. The reaction time (the average retention time in a case where a copolymerization reaction is performed by using a continuous method) varies depending on the conditions such as the catalyst concentration and the polymerization temperature, and can be appropriately selected, but is generally in a range of one minute to three hours, and preferably in a range of ten minutes to 2.5 hours. It is also possible to perform the polymerization in two or more phases with different reaction conditions. The molecular weight of the obtained ethylene•α-olefin copolymer can be adjusted by changing the concentration of hydrogen or the polymerization temperature in the polymerization system. The molecular weight of the ethylene•α-olefin copolymer can also be adjusted by using the amount of the compound (II) being used. In a case where hydrogen is added, the amount of hydrogen is appropriately in a range of approximately 0.001 to 5,000 NL per kilogram of the ethylene•α-olefin copolymer being generated. In addition, a vinyl group and a vinylidene group present at the ends of a molecule in the obtained ethylene •α-olefin copolymer can be adjusted by increasing the polymerization temperature and extremely decreasing the amount of hydrogen being added.

A solvent used in the solution polymerization method is generally an inert hydrocarbon solvent, and is preferably a saturated hydrocarbon having a boiling point in a range of 50° C. to 200° C. at normal pressure. Specific examples thereof include aliphatic hydrocarbons such as pentane, hexane, heptane, octane, decane, dodecane and kerosene; and alicyclic hydrocarbons such as cyclopentane, cyclohexane and methylcyclopentane. Meanwhile, aromatic hydrocarbons such as benzene, toluene and xylene and halogenated hydrocarbons such as ethylene chloride, chlorobenzene and dichloromethane also belong to the scope of the “inert hydrocarbon solvent”, and the use thereof is not limited.

As described above, in the solution polymerization method, not only the organic aluminum oxy compound dissolved in the aromatic hydrocarbon, which was frequently used in the related art, but also modified methyl aluminoxane, such as MMAO, dissolved in an aliphatic hydrocarbon or an alicyclic hydrocarbon can be used. As a result, when the aliphatic hydrocarbon or the alicyclic hydrocarbon is employed as the solvent for the solution polymerization, it becomes possible to almost completely eliminate the possibility of the aromatic hydrocarbon being incorporated into the polymerization system or the ethylene•α-olefin copolymer being generated. That is, the solution polymerization method also has characteristics that the environmental load can be reduced and the influence on human health can be minimized. Meanwhile, in order to suppress the variation in physical properties, it is preferable to melt the ethylene•α-olefin copolymer obtained through the polymerization reaction and other components added as desired by using an arbitrary method, and to knead, granulate and the like the ethylene•α-olefin copolymer and other components.

(Ethylene-Based Resin Composition)

The solar-cell encapsulating material of the embodiment is preferably made of an ethylene-based resin composition containing 100 parts by mass of the ethylene•α-olefin copolymer, 0.1 to 5 parts by mass of a silane coupling agent such as an ethylenic unsaturated silane compound, and 0.1 to 3 parts by mass of a cross-linking agent such as an organic peroxide.

The ethylene-based resin composition preferably contains 0.1 to 4 parts by mass of a silane coupling agent and 0.2 to 3 parts by mass of a cross-linking agent with respect to 100 parts by mass of the ethylene•α-olefin copolymer and particularly preferably contains 0.1 to 3 parts by mass of a silane coupling agent and 0.2 to 2.5 parts by mass of a cross-linking agent with respect to 100 parts by mass of the ethylene•αolefin copolymer.

(Silane Coupling Agent)

When the content of the silane coupling agent is equal to or greater than the lower limit value, the adhesiveness improves.

On the other hand, when the content of the silane coupling agent is equal to or smaller than the upper limit value, the balance between the costs and the performance of the solar-cell encapsulating material is favorable, and it is possible to suppress the amount of an organic peroxide added to cause the silane coupling agent to graft-react with the ethylene•αolefin copolymer during the lamination of the solar cell module. Thus, it is possible to suppress gelation when the solar-cell encapsulating material is obtained in a sheet shape by using an extruder, and to suppress the torque of the extruder, and extrusion sheet molding becomes easy. In addition, it is possible to suppress the generation of unevenness on the surface of the sheet due to gel substances generated in the extruder, and thus it is possible to prevent the degradation of the appearance. In addition, it is possible to prevent the generation of cracks in the sheet when a voltage is applied, and thus it is possible to prevent a decrease in the dielectric breakdown voltage. It is also possible to prevent the degradation of the moisture permeability. In addition, it is possible to suppress the generation of unevenness on the sheet surface, and thus the adhesiveness between the front surface side transparent protection member, the cell, the electrode, and the back surface side protection member becomes favorable during the lamination process of the solar cell module, and the adhesiveness also improves. In addition, the silane coupling agent causes a condensation reaction, and is present in a white line form in the solar-cell encapsulating material, and it is possible to suppress the deterioration of the product appearance. In a case where the amount of the organic peroxide is small, the graft reaction toward the main chain of the ethylene•α-olefin copolymer becomes insufficient, and it is possible to suppress the degradation of adhesiveness.

As the silane coupling agent, a well-known silane coupling agent of the related art can be used, and there is no particular limitation. Specific examples thereof that can be used include vinyltriethoxysilane, vinyltrimethoxysilane, vinyltris(β-methoxyethoxysilane), γ-glycidoxypropyltrimethoxysilane, γ-aminopropyl triethoxysilane and γ-methacryloxypropyl trimethoxysilane. Preferable examples thereof include γ-glycidoxypropyl methoxysilane, γ-aminopropyl triethoxysilane, γ-methacryloxypropyl trimethoxysilane and vinyltriethoxysilane all of which have favorable adhesiveness.

(Organic Peroxide)

The organic peroxide is used as a radical initiator during the graft modification of the silane coupling agent and the ethylene•α-olefin copolymer, and is used as a radical initiator during a cross-linking reaction when the ethylene•α-olefin copolymer is lamination-molded to the solar cell module. When the silane coupling agent is graft-modified into the ethylene•α-olefin copolymer, a solar cell module having a favorable adhesiveness between the glass, the back sheet, the cell, and an electrode can be obtained. When the ethylene•α-olefin copolymer is cross-linked, a solar cell module having excellent heat resistance and adhesiveness can be obtained.

There is no particular limitation regarding the organic peroxide that can be preferably used as long as the organic peroxide is capable of graft-modifying the silane coupling agent into the ethylene•α-olefin copolymer or cross-linking the ethylene•α-olefin copolymer, and the one-minute half-life temperature of the organic peroxide is preferably in a range of 100° C. to 170° C. in consideration of the balance between the productivity during extrusion sheet molding and the cross-linking rate during the lamination molding of the solar cell module. When the one-minute half-life temperature of the organic peroxide is equal to or higher than the lower limit value, gel is not easily generated in the solar-cell encapsulating sheet obtained from the resin composition during sheet molding. It is possible to suppress the generation of unevenness on the surface of the sheet due to the generated gel substances, and thus it is possible to prevent the degradation of the appearance. In addition, it is possible to prevent the generation of cracks in the sheet when a voltage is applied, and thus it is possible to prevent a decrease in the dielectric breakdown voltage. It is also possible to prevent the degradation of the moisture permeability. In addition, it is possible to suppress the generation of unevenness on the sheet surface, and thus the adhesiveness between the front surface side transparent protection member, the cell, the electrode, and the back surface side protection member becomes favorable during the lamination process of the solar cell module, and the adhesiveness also improves. When the one-minute half-life temperature of the organic peroxide is equal to or lower than the upper limit value, it is possible to suppress a decrease in the cross-linking rate during the lamination molding of the solar cell module, and thus it is possible to prevent the degradation of the productivity of the solar cell module. In addition, it is also possible to prevent the degradation of the heat resistance and the adhesiveness of the solar-cell encapsulating material. It is possible to make cross-linking after a lamination process or in an oven appropriate, and it is possible to suppress the contamination of a laminating device or an oven.

A well-known organic peroxide can be used as the organic peroxide. Specific examples of the organic peroxide of which the one-minute half-life temperature is in a range of 100° C. to 170° C. include dilauroyl peroxide, 1,1,3,3-tetramethylbutyl peroxy-2-ethylhexanoate, dibenzoyl peroxide, t-amyl peroxy-2-ethylhexanoate, t-butyl peroxy-2-ethylhexanoate, t-butyl peroxy isobutyrate, t-butyl peroxy maleate, 1,1-di(t-amyl peroxy)-3,3,5-trimethylcyclohexane, 1,1-di(t-amyl peroxy)cyclohexane, t-amyl peroxy isononanoate, t-amyl peroxy normal octoate, 1,1-di(t-butyl peroxy)-3,3,5-trimethylcyclohexane, 1,1-di(t-butyl peroxy) cyclohexane, t-butyl peroxy isopropyl carbonate, t-butyl peroxy-2-ethylhexyl carbonate, 2, 5-dimethyl-2, 5-di(benzoyl peroxy) hexane, t-amyl-peroxy benzoate, t-butyl peroxy acetate, t-butyl peroxy isononanoate, 2,2-di(t-butyl peroxy)butane, and t-butyl peroxy benzoate. Preferable examples thereof include dilauroyl peroxide, t-butyl peroxy isopropyl carbonate, t-butyl peroxy acetate, t-butyl peroxy isononanoate, t-butyl peroxy-2-ethylhexyl carbonate, and t-butyl peroxy benzoate. One type of the organic peroxide may be singly used or two or more types of the organic peroxides may be used in a mixture form.

The content of the organic peroxide in the solar-cell encapsulating material is preferably 0.005 to 5.0 parts by mass, more preferably 0.1 to 3.0 parts by mass, still more preferably 0.2 to 3.0 parts by mass, and particularly preferably 0.2 to 2.5 parts by mass with respect to 100 parts by mass of the ethylene•α-olefin copolymer.

(Ultraviolet Absorbing Agent, Light Stabilizer, and Heat-Resistance Stabilizer)

The ethylene-based resin composition preferably contains at least one type of additive selected from the group consisting of an ultraviolet absorbing agent, a light stabilizer, and a heat-resistance stabilizer. The blending content of these additives is preferably 0.005 to 5 parts by mass, with respect to 100 parts by mass of the ethylene•α-olefin copolymer. The ethylene-based resin composition preferably contains at least two types of additives selected from the above-described three types of additives and particularly preferably contains all of the three types of additives. When the blending amount of the additives is within the above-described range, an effect of improving the resistance to high temperature and high humidity, the resistance to heat cycles, weather resistance stability, and heat resistance stability is sufficiently ensured, and it is possible to prevent the degradation of the transparency of the solar-cell encapsulating material or the adhesiveness between the glass, the back sheet, the cell, the electrode, and aluminum, which is preferable.

As the ultraviolet absorbing agent, specifically, a benzophenone-based ultraviolet absorbing agent such as 2-hydroxy-4-normal-octyloxy benzophenone, 2-hydroxy-4-methoxy benzophenone, 2,2-dihydroxy-4-methoxy benzophenone, 2-hydroxy-4-methoxy-4-carboxy benzophenone, and 2-hydroxy-4-N-octoxy benzophenone; a benzotriazole-based ultraviolet absorbing agent such as 2-(2-hydroxy-3,5-di-t-butyl phenyl)benzotriazole and 2-(2-hydroxy-5-methyl phenyl)benzotriazole; or a salicylic acid ester-based ultraviolet absorbing agent such as phenyl salicylate and p-octyl phenyl salicylate is used.

As the light stabilizer, hindered amine-based light stabilizers and hindered piperidine-based light stabilizers such as bis(2,2,6,6-tetramethyl-4-piperidyl)sebacate, and poly[{6-(1,1,3,3-tetramethyl butyl)amino-1,3,5-triazine-2,4-diyl} {(2,2,6,6-tetramethyl-4-piperidyl)imino}hexamethylene {(2,2,6,6-tetramethyl-4-piperidyl)imino}] are preferably used.

Specific examples of the heat-resistance stabilizer include a phosphite-based heat-resistance stabilizer such as tris(2,4-di-tert-butylphenyl)phosphite, bis[2,4-bis(1,1-dimethylethyl)-6-methylphenyl]ethyl ester phosphite, tetrakis(2,4-di-tert-butylphenyl) [1,1-biphenyl]-4,4′-diyl bis phosphonites, and bis(2,4-di-tert-butylphenyl)pentaerythritol diphosphite; a lactone-based heat-resistance stabilizer such as a reaction product between 3-hydroxy-5,7-di-tert-butyl-furan-2-one and o-xylene; a hindered phenol-based heat-resistance stabilizer such as 3,3′,3″,5,5′,5″-hexa-tert-butyl-a,a′,a″-(methylene-2,4,6-triyl)t ri-p-cresol, 1,3,5-trimethyl-2,4,6-tris(3,5-di-tert-butyl-4-hydroxyphenyl)ben zylbenzene, pentaerythritol tetrakis[3-(3,5-di-tert-butyl-4-hydroxyphenyl)propionate], octadecyl-3-(3,5-di-tert-butyl-4-hydroxyphenyl)propionate, and thiodiethylene bis[3-(3,5-di-tert-butyl-4-hydroxyphenyl)propionate]; a sulfur-based heat-resistance stabilizer; and an amine-based heat-resistance stabilizer. It is also possible to singly use one type of the heat-resistance stabilizer or use two or more types of the heat-resistance stabilizers in a combination form. Among these materials, the phosphite-based heat-resistance stabilizer and the hindered phenol-based heat-resistance stabilizer are preferable.

(Other Additives)

The ethylene-based resin composition configuring the solar-cell encapsulating material is capable of appropriately containing various components other than the components described above in detail within the scope of the purpose of the invention. For example, other than the ethylene•α-olefin copolymer, various polyolefins, styrene-based or ethylene-based block copolymers, propylene-based polymers, and the like can be included. The content of the above-described components may be in a range of 0.0001 to 50 parts by mass, and preferably in a range of 0.001 to 40 parts by mass with respect to 100 parts by mass of the ethylene•α-olefin copolymer. In addition, it is possible to appropriately include one or more additives selected from various resins other than polyolefins and/or various rubbers, a plasticizer, a filler, a pigment, a dye, an antistatic agent, an antimicrobial agent, an antifungal agent, a flame retardant, a cross-linking assistant, a dispersant and the like.

Particularly, in a case where the cross-linking assistant is contained, when the blending amount of the cross-linking assistant is in a range of 0.05 to 5 parts by mass with respect to 100 parts by mass of the ethylene•α-olefin copolymer, the solar-cell encapsulating material is capable of having an appropriate cross-linking structure, and is capable of improving heat resistance, mechanical properties, and adhesiveness, which is preferable.

As the cross-linking assistant, a well-known cross-linking assistant of the related art which is generally used with respect to olefin-based resins can be used. This cross-linking assistant is a compound in which two double bonds or more are provided in a molecule may be used. Specific examples thereof include monoacrylate such as t-butyl acrylate, lauryl acrylate, cetyl acrylate, stearyl acrylate, 2-methoxyethyl acrylate, ethyl carbitol acrylate, and methoxy tripropylene glycol acrylate; monomethacrylate such as t-butyl methacrylate, lauryl methacrylate, cetyl methacrylate, stearyl methacrylate, methoxyethylene glycol methacrylate, methoxypolyethylene glycol methacrylate; diacrylate such as 1,4-butanediol diacrylate, 1,6-hexanediol diacrylate, 1,9-nonanediol diacrylate, neopentyl glycol diacrylate, diethylene glycol diacrylate, tetraethylene glycol diacrylate, polyethylene glycol diacrylate, tripropylene glycol diacrylate, and polypropylene glycol diacrylate; dimethacrylate such as 1,3-butanediol dimethacrylate, 1,6-hexanediol dimethacrylate, 1,9-nonanediol dimethacrylate, neopentyl glycol dimethacrylate, ethylene glycol dimethacrylate, diethylene glycol dimethacrylate, triethylene glycol dimethacrylate, and polyethylene glycol dimethacrylate; triacrylate such as trimethylol propane triacrylate, tetramethylol methane triacrylate, and pentaerythritol triacrylate; trimethacrylate such as trimethylol propane trimethacrylate, and trimethylol ethane trimethacrylate; tetraacrylate such as pentaerythritol tetraacrylate and tetramethylol methane tetraacrylate; divinyl aromatic compounds such as divinylbenzene and di-i-propenyl benzene; cyanurate such as triallyl cyanurate and triallyl isocyanurate; diallyl compounds such as diallyl phthalate; triallyl compounds; oxime such as p-quinone dioxime and p-p′-dibenzoyl quinone dioxime; and maleimide such as phenyl maleimide.

Among these cross-linking assistants, diacrylate, dimethacrylate, divinyl aromatic compound, triacrylate such as trimethylol propane triacrylate, tetramethylol methane triacrylate, and pentaerythritol triacrylate; trimethacrylate such as trimethylolpropane trimethacrylate and trimethylolethane trimethacrylate; tetraacrylate such as pentaerythritol tetraacrylate and tetramethylolmethane tetraacrylate; cyanurate such as triallyl cyanurate and triallyl isocyanurate; diallyl compounds such as diallyl phthalate; triallyl compounds; oxime such as p-quinone dioxime and p-p′-dibenzoyl quinone dioxime; and maleimide such as phenyl maleimide are preferable. Further, among these materials, triallyl isocyanurate is particularly preferable since the occurrence of bubbles in the solar-cell encapsulating material after lamination or the balance of the cross-linking characteristics is most favorable.

(Solar-Cell Encapsulating Material)

The solar-cell encapsulating material of the embodiment has excellent balance among adhesiveness to various solar cell members such as glass, a back sheet, a thin-film electrode, aluminum, and a solar cell element, heat resistance, extrusion moldability, and cross-linking characteristics, and, has excellent balance among transparency, flexibility, appearance, weather resistance, volume intrinsic resistance, electrical insulating properties, moisture permeability, electrode corrosiveness, and process stability. Thus, the solar-cell encapsulating material is preferably used as a solar-cell encapsulating material for well-known solar cell modules of the related art. As a manufacturing method of the solar-cell encapsulating material of the preset embodiment, a method that is generally used can be used, but the solar-cell encapsulating material is preferably manufactured by performing molten blending by using a kneader, a Banbury mixer, an extruder, or the like. Particularly, manufacturing by using an extruder which enables continuous production is preferable.

The solar-cell encapsulating material is one of embodiments in which the overall shape is also preferably a sheet shape. In addition, a solar-cell encapsulating material which has at least one layer of a sheet made of the ethylene-based resin composition and has been complexed with another layer can also be preferably used. The thickness of the layer of the solar-cell encapsulating material is generally 0.01 to 2 mm, preferably 0.05 to 1.5mm, further preferably 0.1 to 1.2 mm, particularly preferably 0.2 to 1 mm, more preferably 0.3 to 0.9 mm, and most preferably 0.3 to 0.8 mm. When the thickness is in the above range, it is possible to suppress occurrence of damage of the glass, the solar cell element, a thin-film electrode in the laminate process, and to obtain high photovoltaic amount by ensuring sufficient light transmittance. In addition, it is preferable that lamination molding can be performed for a solar cell module at a low temperature.

A molding method of the solar-cell encapsulating material sheet is not particularly limited. However, various well-known molding methods (cast molding, extrusion sheet molding, calender molding, inflation molding, injection molding, compression molding, and the like) maybe employed. Particularly, the most preferable embodiment is that a composition in which the ethylene•α-olefin copolymer and various additive are blended together by blending the ethylene•α-olefin copolymer, a silane coupling agent, an organic peroxide, an ultraviolet absorbing agent, a light stabilizer, a heat-resistance stabilizer, and other additives as necessary in, for example, a bag such as a polyethylene bag with a human force or by using a stirring and mixing machine such as a Henschel mixer, a tumbler mixer, and a Super mixer in an extruder is put into a hopper for extrusion sheet molding, extrusion sheet molding is performed while molten kneading is performed, and thereby a sheet-shape solar-cell encapsulating material is obtained.

When pelletization is performed once in the blended composition by using an extruder, and a sheet is produced by extrusion molding or press molding, pellets are obtained by, generally, immersing a water layer or cooling and cutting a strand by using an underwater cutter-type extruder. Thus, moisture is attached to pellets, and the deterioration of the additives, particularly, the silane coupling agent occurs. For example, when a sheet is produced by using an extruder again, a condensation reaction progresses in the silane coupling agent, and there is a tendency that adhesiveness degrades, which is not preferable. In addition, even in a case where a master batch of the ethylene•α-olefin copolymer and the additives excluding the organic peroxide or the silane coupling agent (stabilizers such as the heat-resistance stabilizer, the light stabilizer, and the ultraviolet absorbing agent) is formed in advance by using an extruder, then, the organic peroxide or the silane coupling agent is blended, and a sheet molding is formed again by using the extruder or the like, the stabilizers such as the heat-resistance stabilizer, the light stabilizer, and the ultraviolet absorbing agent have been subjected to the extruder twice, and thus there is a tendency that the stabilizers deteriorate, and long-term stability such as weather resistance or heat resistance degrades, which is not preferable.

As the extrusion temperature range, the extrusion temperature is preferably 100° C. to 130° C. When the extrusion temperature is set to equal to or higher than the lower limit value, it is possible to improve productivity of the solar-cell encapsulating material. When the extrusion temperature is set to equal to or lower than the upper limit value, when the solar-cell encapsulating material is obtained by forming a sheet of the resin composition by using an extruder, gelation does not easily occur. Thus, an increase in the torque of the extruder is prevented, and sheet molding can be easily performed. Since unevenness is not easily generated on the surface of the sheet, it is possible to prevent the degradation of appearance. In addition, it is possible to suppress the generation of cracks in the sheet when a voltage is applied, and thus it is possible to prevent a decrease in the dielectric breakdown voltage. It is also possible to prevent the degradation of the moisture permeability. In addition, unevenness is not easily generated on the sheet surface, and thus the adhesiveness between the front surface side transparent protection member, the cell, the electrode, and the back surface side protection member becomes favorable during the lamination process of the solar cell module, and the adhesiveness also improves.

Embossing may be performed on surfaces of the solar-cell encapsulating material sheet (or the layer). When the solar-cell encapsulating material sheet surface is decorated by embossing, blocking between the encapsulating sheets or between the encapsulating sheet and other sheets can be prevented. Because embossing causes the storage elastic modulus of the solar-cell encapsulating material (an encapsulating sheet for a solar cell) to be reduced, the embosses serve as cushions for the solar cell element and the like when the solar-cell encapsulating material sheet and the solar cell element are laminated. Thus, it is possible to prevent damage of the solar cell element.

The solar-cell encapsulating material sheet may be configured only by layers made of the solar-cell encapsulating material of the embodiment or may have layers other than layers containing the solar-cell encapsulating material (hereinafter, also referred to as “the other layers”). Examples of the other layers include, if classified depending on the purposes, hard coat layers, adhesive layers, anti-reflection layers, gas barrier layers, anti-fouling layers, and the like which are to protect front surfaces or back surfaces. If classified depending on materials, examples thereof include layers made of an ultraviolet-curable resin, layers made of a thermosetting resin, layers made of a polyolefin resin, layers made of a carboxylic acid-modified polyolefin resin, layers made of a fluorine-containing resin, layers made of a cyclic olefin (co) polymer, layers made of an inorganic compound, and the like.

The positional relationship between layers made of the solar-cell encapsulating material of the embodiment and the other layers is not particularly limited, and a preferable layer configuration is appropriately selected in consideration of the relationship with the object of the present invention. That is, the other layers may be provided between two or more layers made of the solar-cell encapsulating material, maybe provided on the outermost layer of the solar-cell encapsulating material sheet, or may be provided at other places. In addition, the other layers may be provided only on one surface of a layer made of the solar-cell encapsulating material, or the other layers may be provided on both surfaces. The number of the other layers is not particularly limited, an arbitrary number of the other layers maybe provided, or the other layers may not be provided.

From the viewpoint of reducing costs by simplifying the structure and from the viewpoint of extremely decreasing interface reflection and effectively using light, the solar-cell encapsulating material sheet maybe produced only by layers made of the solar-cell encapsulating material of the embodiment without providing the other layers. However, the other layers may be appropriately provided as long as the other layers are necessary or useful in consideration of the purposes. In a case in which the other layers are provided, the method for stacking layers made of the solar-cell encapsulating material of the embodiment and other layers is not particularly limited, but a method in which a stacked body is obtained through co-extrusion by using a well-known melt extruder such as a casting molder, an extrusion sheet molder, an inflation molder, or an injection molder or a method in which a stacked body is obtained by melting or heating-laminating one layer on another layer that has been formed in advance is preferable. In addition, layers may be stacked by using a dry laminate method, a heat laminate method or the like in which an appropriate adhesive (for example, a maleic acid anhydride-modified polyolefin resin (trade name “ADOMER (registered trademark) ” manufactured by Mitsui Chemicals, Inc., trade name “MODIC (registered trademark)” manufactured by Mitsubishi Chemical Corporation, or the like), a low- (non-) crystalline soft polymer such as an unsaturated polyolefin, an acrylic adhesive including an ethylene/acrylic acid ester/maleic acid anhydride-ternary copolymer (trade name “BONDINE (registered trademark)” manufactured by Sumika CdF Chemical Company Limited. or the like), an ethylene/vinyl acetate-based copolymer, an adhesive resin composition containing what has been described above, or the like) is used. An adhesive having heat resistance in a range of approximately 120° C. to 150° C. is preferably used as the adhesive, and preferable examples thereof include polyester-based adhesives, and polyurethane-based adhesives. In addition, in order to improve the adhesiveness between both surfaces, for example, a silane-based coupling treatment, a titanium-based coupling treatment, a corona treatment, a plasma treatment, or the like may be used.

2. Regarding Solar Cell Module

Examples of the solar cell module include a crystalline solar cell module obtained by, generally, sandwiching and stacking a solar cell element formed of single crystal silicon, polycrystalline silicon, or the like between the solar-cell encapsulating material sheets and covering both the front and back surfaces with a protective sheet. That is, a typical solar cell module has a configuration of a protective sheet for a solar cell module (front surface side transparent protection member)/a solar-cell encapsulating material sheet/a solar cell element/a solar-cell encapsulating material sheet/a protective sheet for a solar cell module (back surface side protection member). However, a solar cell module which is one of the preferable embodiments of the present invention is not limited to the above-described configuration, and it is possible to appropriately remove some of the respective layers or appropriately provide other layers within the scope of the object of the present invention. Examples of other layers described above include an adhesive layer, an impact absorptive layer, a coating layer, an anti-reflection layer, a back side re-reflection layer, a light diffusion layer, and the like. These layers are not particularly limited. However, considering the purpose for providing each of the layers or the characteristics of each of the layers, the layers may be respectively provided at proper positions.

(n-type Crystalline Silicon-Based Solar Cell Module)

As crystalline silicon-based solar cell elements, there are n-type crystalline silicon-based solar cell elements including a p-type semiconductor layer formed on an n-type semiconductor as a substrate and p-type crystalline silicon-based solar cell elements including an n-type semiconductor layer formed on a p-type semiconductor as a substrate. It is known that n-type crystalline silicon-based solar cell modules having a structure in which an n-type semiconductor is used as a substrate have stronger resistance to impurities compared with structures in which a p-type semiconductor is used as a substrate, and, theoretically, the energy conversion efficiency can be easily increased.

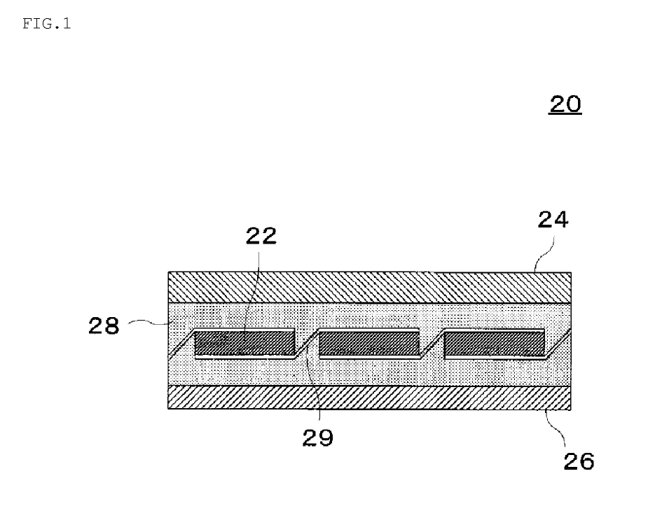

FIG. 1 is a schematic cross-sectional view illustrating an embodiment of an n-type crystalline silicon-based solar cell module of the present invention. As illustrated in FIG. 1, a solar cell module 20 has a plurality of n-type crystalline silicone-based solar cell elements 22 electrically connected to each other through an interconnector 29 and a pair of a front surface side transparent protection member 24 and a back surface side protection member 26 which sandwich the n-type crystalline silicone-based solar cell elements, and an encapsulating layer 28 is provided between these protection members and a plurality of the solar cell elements 22. The encapsulating layer 28 is obtained by attaching the solar-cell encapsulating material sheets of the embodiment and then heating and pressing the solar-cell encapsulating material sheet and is in contact with electrodes formed on the light-receiving surfaces and the back surfaces of the solar cell elements 22. The electrodes refer to power collection members respectively formed on the light-receiving surfaces and the back surfaces of the solar cell elements 22, and include power collection lines, tabbing bus bars, a back surface electrode layer, and the like.

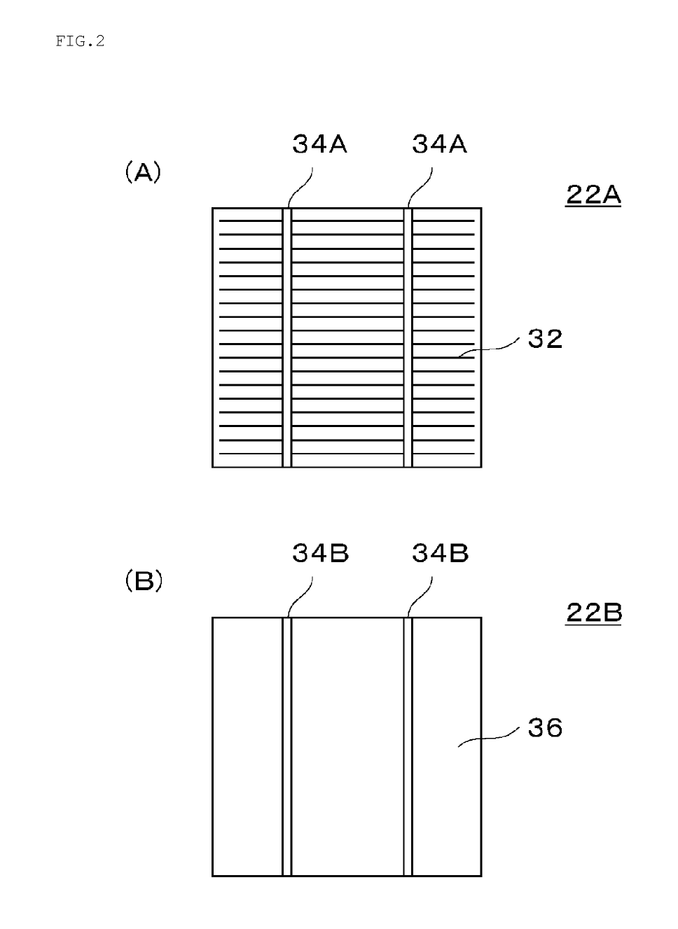

FIG. 2 is a schematic plan view illustrating one configuration example of a light-receiving surface and aback surface of the n-type crystalline silicon-based solar cell element. FIG. 2 illustrates an example of the constitutions of the light-receiving surface 22A and the back surface 22B of the solar cell element 22. As illustrated in FIG. 2(A), on the light-receiving surface 22A of the solar cell element 22, a number of power collection lines 32 formed in a line shape and tabbing bus bars 34A which collect charges from the power collection lines 32 and are connected to the interconnector 29 (FIG. 1) are formed. As illustrated in FIG. 2(B), on the back surface 22B of the solar cell element 22, a conductive layer (back surface electrode) 36 is formed on the entire surface, and tabbing bus bars 34B which collect charges from the conductive layer 36 and are connected to the interconnector 29 (FIG. 1) are formed on the conductive layer. The line width of the power collection line 32 is, for example, approximately 0.1 mm; the line width of the tabbing bus bar 34A is, for example, approximately 2 to 3 mm; the line width of the tabbing bus bar 34B is, for example, approximately 5 to 7 mm. The thicknesses of the power collection line 32, the tabbing bus bar 34A, and the tabbing bus bar 34B are, for example, approximately 20 to 50 μm.

The power collection line 32, the tabbing bus bar 34A, and the tabbing bus bar 34B preferably include highly conductive metal. Examples of the highly conductive metal include gold, silver, copper, and the like, and, from the viewpoint of high conductivity or strong corrosion resistance, silver, a silver compound, an alloy containing silver, or the like is preferable. The conductive layer 36 preferably includes not only highly conductive metal but also a component that strongly reflects light, for example, aluminum from the viewpoint of reflecting light received on the light-receiving surface and improving the incident photon-to-current conversion efficiency of the solar cell element. The power collection line 32, the tabbing bus bar 34A, the tabbing bus bar 34B, and the conductive layer 36 are formed by applying conductive material paint including the highly conductive metal on the light-receiving surface 22A or the back surface 22B of the solar cell element 22 by, for example, screen printing in a coated film thickness of 50 μm, then, drying the coated film, and, if necessary, baking the coated film at, for example, 600° C. to 700° C.

The front surface side transparent protection member 24 is disposed on the light-receiving surface side and thus needs to be transparent. Examples of the front surface side transparent protection member 24 include transparent glass plates, transparent resin films, and the like. On the other hand, the back surface side protection member 26 does not need to be transparent, and the material thereof is not particularly limited. Examples of the back surface side protection member 26 include glass substrates, plastic films, and the like, but glass substrates are preferably used from the viewpoint of durability or transparency.

The solar cell module 20 can be obtained by an arbitrary manufacturing method. The solar cell module 20 can be obtained by, for example, a step of obtaining a stacked body in which the back surface side protection member 26, the solar-cell encapsulating material sheet, a plurality of the solar cell elements 22, the solar-cell encapsulating material sheet, and the front surface side transparent protection member 24 are stacked in this order; a step of pressing and attaching the stacked body by using a laminator or the like and, if necessary, heating the stacked body at the same time; and a step of, if necessary, further heating the stacked body after the above-described steps so as to cure the encapsulating material.

In the solar cell element, generally, a power collection electrode for extracting generated electricity is disposed. Examples of the power collection electrode include bus bar electrodes, finger electrodes, and the like. Generally, the power collection electrode is disposed on both surfaces (the front surface and the back surface) of the solar cell element; however, when the power collection electrode is disposed on the light-receiving surface, the power collection electrode blocks light, and thus a problem of a decrease in the power generation efficiency may be caused.

Recently, in order to improve the power generation efficiency, using a back contact-type solar cell element in which it is not necessary to dispose the power collection electrode on the light-receiving surface is considered. In an aspect of the back contact-type solar cell element, p-doped regions and n-doped regions are alternatively provided on the back surface side provided on a side opposite to the light-receiving surface of the solar cell element. In another aspect of the back contact-type solar cell element, a p/n junction is formed on a substrate provided with a through hole, a dope layer is formed on the inner wall of the through hole and on the front surface (light-receiving surface) side up to the through hole peripheral portion on the back surface side, and a current on the light-receiving surface is extracted on the back surface side.

Generally, in a solar cell system, several to several tens of the solar cell modules are connected to each other in series, and a small-scale residential solar cell system is operated in 50 to 500 V, and a large-scale solar cell system called mega solar is operated in 600 to 1,000 V. For the outer frame of the solar cell module, an aluminum frame or the like is used in order to maintain strength and the like, and, from the viewpoint of safety, there are many cases where aluminum is earthed (grounded). As a result, when power is generated by a solar cell, a voltage difference caused by power generation is generated between a glass surface having a lower electrical resistance than in the encapsulating material and the solar cell element.

As a result, in the solar-cell encapsulating material encapsulating the gap between a power generation cell and a glass or aluminum frame, there is a demand for favorable electrical characteristics such as high electrical insulating properties and high resistance.

Particularly, the encapsulating layer stacked below a photovoltaic element configuring the solar cell module needs to have adhesiveness to the encapsulating layer, the electrode, and the back surface protection layer which are stacked on the upper portion of the photovoltaic element. In addition, in order to maintain the flatness of the back surface of the solar cell element as the photovoltaic element, the solar cell element needs to be thermoplastic. In order to protect the solar cell element as the photovoltaic element, the solar cell element needs to be excellent in scratch resistance, impact absorptive properties, and the like.

The encapsulating layer desirably has heat resistance. Particularly, in the manufacturing of the solar cell module, it is desirable to prevent an ethylene-based resin composition configuring the encapsulating layer from being modified, deteriorated, or decomposed by a heating action in a lamination method or the like in which the encapsulating layer is vacuum-suctioned, heated, and pressed or the action of heat such as sunlight in the long-term use of the solar cell module or the like. If additives and the like included in the ethylene-based resin composition elute or decomposed substances are generated, the additives and the like or the decomposed substances act on the electromotive force surface (element surface) of the solar cell element, and the function, performance, and the like thereof deteriorate. Thus, heat resistance is an essential characteristic for the encapsulating layer in the solar cell module. The encapsulating layer preferably has excellent moisture-proof properties. In this case, it is possible to prevent the permeation of moisture from the back surface side of the solar cell module, and it is possible to prevent the corrosion and deterioration of the photovoltaic element in the solar cell module.

Unlike the encapsulating layer stacked on the photovoltaic element, the above-described encapsulating layer does not always need to be transparent. The solar-cell encapsulating material of the embodiment has the above-described characteristics and can be preferably used as a solar-cell encapsulating material on the back surface side of a crystalline solar cell module and a solar-cell encapsulating material in a thin-film type solar cell module which is weak to moisture infiltration.

The solar cell module of the embodiment may appropriately have an arbitrary member within the scope of the object of the present invention. Typically, an adhesive layer, an impact absorptive layer, a coating layer, an anti-reflection layer, a back side re-reflection layer, a light diffusion layer, and the like may be provided, but the arbitrary member is not limited thereto. Locations at which these layers are provided are not particularly limited, and the layers can be provided at appropriate locations in consideration of the object of the provision of the layers and the characteristics of the layers.

(Front Surface Side Transparent Protection Member for Solar Cell Module)

The front surface side transparent protection member for a solar cell module which is used in the solar cell module is not particularly limited, but is located on the outermost surface layer of the solar cell module, and thus preferably has performances for ensuring long-term reliability for the outdoor exposure of the solar cell module including weather resistance, water repellency, contamination resistance, and mechanical strength. In addition, the front surface side transparent protection member for a solar cell module is preferably a sheet having a small optical loss and high transparency for the effective use of sunlight.

Examples of the material of the front surface side transparent protection member for a solar cell module include resin films made of a polyester resin, a fluorine resin, an acryl resin, a cyclic olefin (co) polymer, an ethylene-vinyl acetate copolymer, and the like, glass substrates, and the like. The resin film is preferably a polyester resin having excellent transparency, strength, cost and the like, and particularly preferably a polyethylene terephthalate resin, a fluorine resin having favorable weather resistance, or the like. Examples of the fluorine resin include an ethylene-tetrafluoroethylene copolymer (ETFE), a polyvinyl fluoride resin (PVF), a polyvinylidene fluoride resin (PVDF), a polytetrafluoroethylene resin (TFE), a fluorinated ethylene/propylene copolymer (FEP) and a polytrifluorochloroethylene resin (CTFE). The polyvinylidene fluoride resin is excellent from the viewpoint of weather resistance, and the ethylene-tetrafluoroethylene copolymer is excellent in terms of satisfying both weather resistance and mechanical strength. In addition, in order to improve the adhesiveness to materials configuring other layers such as an encapsulating material layer, it is desirable to perform a corona treatment and a plasma treatment on the front surface side transparent protection member. In addition, it is also possible to use a sheet that has been subjected to a stretching treatment, for example, a biaxially stretched polypropylene sheet to improve the mechanical strength.

In a case where a glass substrate is used as the front surface side transparent protection member for a solar cell module, the full light transmittance of the glass substrate at a wavelength in a range of 350 to 1,400 nm is preferably 80% or greater and more preferably 90% or greater. As such a glass substrate, a white glass plate slightly absorbing light in the infrared range is generally used, but a blue glass plate may be used as long as the thickness is 3 mm or smaller since the influence on the output characteristics of the solar cell module is small. In addition, in order to increase the mechanical strength of the glass substrate, it is possible to obtain reinforced glass by a thermal treatment, but a float glass plate on which no thermal treatment is performed may also be used. In order to suppress reflection on the light-receiving surface side of the glass substrate, anti-reflection coating may be performed.

(Back Surface Side Protection Member for Solar Cell Module)

The back surface side protection member for a solar cell module which is used in the solar cell module is not particularly limited, but is located on the outermost surface layer of the solar cell module, similar to the front surface side transparent protection member, the back surface side protection member needs to have various characteristics such as weather resistance and mechanical strength. Thus, the back surface side protection member for a solar cell module may be configured by using the same materials as the front surface side transparent protection member. That is, various materials described above which are used as the front surface side transparent protection member can also be used as the back surface side protection member. Particularly, it is possible to preferably use a polyester resin and glass. Since the back surface side protection member is not required to allow the penetration of sunlight, transparency required for the front surface side transparent protection member is not always required. Thus, a reinforcement plate may be attached in order to increase the mechanical strength of the solar cell module or to prevent strain and warpage caused by temperature changes. Examples of the reinforcement plate that can be preferably used include a steel plate, a plastic plate, a glass fiber reinforced plastic (FRP) plate, and the like.

The solar-cell encapsulating material of the embodiment may be integrated with the back surface side protection member for a solar cell module. When the solar-cell encapsulating material and the back surface side protection member for a solar cell module are integrated together, it is possible to shorten a step of cutting the solar-cell encapsulating material and the back surface side protection member for a solar cell module in a module side during module assembly. In addition, when a step of laying up an integrated sheet is used as the step of respectively laying up the solar-cell encapsulating material and the back surface side protection member for a solar cell module, it is also possible to shorten and remove the lay-up step. In a case where the solar-cell encapsulating material and the back surface side protection member for a solar cell module are integrated together, the stacking method for the solar-cell encapsulating material and the back surface side protection member for a solar cell module is not particularly limited. The stacking method is preferably a method in which a stacked body is obtained through co-extrusion by using a well-known melt extruder such as a casting molder, an extrusion sheet molder, an inflation molder or an injection molder; or a method in which one layer is melted or laminated by heating on the other layer that has been formed in advance, and thereby a stacked body is obtained.

In addition, the solar-cell encapsulating material and the back surface side protection member for a solar cell module may be stacked by using a dry laminate method, a heat laminate method or the like in which an appropriate adhesive (for example, a maleic acid anhydride-modified polyolefin resin (trade name “ADOMER (registered trademark) ” manufactured by Mitsui Chemicals, Inc., trade name “MODIC (registered trademark) ” manufactured by Mitsubishi Chemical Corporation, or the like), a low- (non-) crystalline soft polymer such as an unsaturated polyolefin, an acrylic adhesive including an ethylene/acrylic acid ester/maleic acid anhydride-ternary copolymer (trade name “BONDINE (registered trademark)” manufactured by Sumika CdF Chemical Company Limited. or the like), an ethylene/vinyl acetate-based copolymer, an adhesive resin composition containing what has been described above, or the like) is used.

An adhesive having heat resistance in a range of approximately 120° C. to 150° C. is preferably used as the adhesive, and, specifically, a polyester-based adhesive, or a polyurethane-based adhesive is preferable. In addition, in order to improve the adhesiveness between both layers, for example, a silane-based coupling treatment, a titanium-based coupling treatment, a corona treatment, a plasma treatment, or the like may be performed on at least one layer.

(Solar Cell Element)

The n-type crystalline silicon-based solar cell element used in the solar cell module of the embodiment refers to a solar cell element in which a p-type semiconductor layer is formed on an n-type semiconductor as a substrate.

A silicon-based solar cell element has excellent characteristics, but it is known that the silicon-based solar cell element is easily broken due to stress, impact, or the like from the outside. The solar-cell encapsulating material of the embodiment has excellent flexibility, and thus has a strong effect of preventing the breakage of the solar cell element by absorbing stress, impact, and the like on the solar cell element. Thus, in the solar cell module of the embodiment, a layer made of the solar-cell encapsulating material of the embodiment is desirably directly joined to the solar cell element.

(Electrode)

The configuration and the material of the electrode used in the solar cell module are not particularly limited; however, in a specific example, the electrode has a structure in which a transparent conductive film and a metal film are stacked together. The transparent conductive film is made of SnO₂, ITO, ZnO, or the like. The metal film is made of metal such as silver, gold, copper, tin, aluminum, cadmium, zinc, mercury, chromium, molybdenum, tungsten, nickel, or vanadium. These metal films may be singly used or may be used as a complexed alloy. The transparent conductive film and the metal film are formed by a method such as CVD, sputtering, or deposition.

(Manufacturing Method of Solar Cell Module)

A manufacturing method of a solar cell module of the embodiment includes (i) a step in which the front surface side transparent protection member, the solar-cell encapsulating material of the embodiment, a solar cell element (cell), a solar-cell encapsulating material, and a back surface side protection member are stacked in this order, and thereby a stacked body is formed, and (ii) a step in which the obtained stacked body is pressurized and heated so as to be integrated.

In Step (i), a surface of the solar-cell encapsulating material on which an uneven shape (embossed shape) is formed is preferably disposed so as to be on the solar cell element side.

In Step (ii), the stacked body obtained in Step (i) is heated and pressurized by using a vacuum laminator or a hot press according to an ordinary method so as to be integrated (encapsulated). During the encapsulating, since the solar-cell encapsulating material of the embodiment has high cushioning properties, it is possible to prevent damage to the solar cell element. In addition, since the solar-cell encapsulating material has favorable deaeration properties, air is not trapped, and it is possible to manufacture high-quality products with a favorable yield.

When the solar cell module is manufactured, the ethylene-based resin composition configuring the solar-cell encapsulating material is cured through cross-linking. The cross-linking step may be performed at the same time as Step (ii) or after Step (ii).

In a case where the cross-linking step is performed after Step (ii), in Step (ii), the stacked body is heated in a vacuum for three to six minutes under conditions of a temperature in a range of 125° C. to 160° C. and a vacuum pressure of equal to or less than 10 Torr; then, pressurization by the atmospheric pressure is performed for approximately one minute to 15 minutes, and thereby the stacked body is integrated. The cross-linking step performed after Step (ii) can be performed by using an ordinary method, and, for example, a tunnel-type continuous cross-linking furnace may be used, or a tray-type batch cross-linking furnace maybe used. In addition, the cross-linking conditions are generally a temperature in a range of 130° C. to 155° C. for approximately 20 minutes to 60 minutes.

Meanwhile, in a case where the cross-linking step is performed at the same time as Step (ii), it is possible to perform the cross-linking step in the same manner as the case where the cross-linking step is performed after Step (ii) except for the fact that the heating temperature in Step (ii) is set in a range of 145° C. to 170° C. and the pressurization time at the atmospheric pressure is set in a range of six minutes to 30 minutes. Since the solar-cell encapsulating material of the embodiment contains the specific organic peroxide, and thus has excellent cross-linking characteristics, the solar cell module does not need to pass through two phases of an adhering step in Step (ii), is capable of being completed at a high temperature within a short period of time, the cross-linking step performed after Step (ii) may not be performed, and it is possible to significantly improve the productivity of the module.

In any case, during the manufacturing of the solar cell module of the embodiment, the solar-cell encapsulating material is temporarily adhered to the solar cell elements or the protection member at a temperature at which a cross-linking agent is not substantially decomposed and the solar-cell encapsulating material of the embodiment is melted, and then sufficient adhering and cross-linking of the encapsulating material may be performed by increasing the temperature. An additive formulation with which various conditions can be satisfied may be selected, and for example, the type and impregnation amount of the above-described cross-linking agent, the above-described cross-linking assistant, and the like may be selected.

The cross-linking is preferably performed until the gel fraction of the cross-linked solar-cell encapsulating material reaches 50% to 95%. The gel fraction is more preferably 50% to 90%, more preferably 60% to 90%, and most preferably 65% to 90%. The computation of the gel fraction can be performed by the following method. For example, 1 g of a sample of the encapsulating material sheet is sampled from the solar cell module, and soxhlet extraction is performed for ten hours in boiling toluene. The extraction liquid is filtered by using a stainless steel mesh having 30 meshes, and the mesh is decompressed and dried at 110° C. for eight hours. The weight of residue remaining on the mesh is measured, and the percentage (%) of the weight of the residue remaining on the mesh with respect to the sample amount (1 g) before the treatment is considered as the gel fraction.

When the gel fraction is equal to or greater than the lower limit value, the heat resistance of the solar-cell encapsulating material becomes favorable, and it is possible to suppress the degradation of adhesiveness in, for example, a constant temperature and humidity test at 85° C.×85% RH, a high-intensity xenon radiation test at a black panel temperature of 83° C., a heat cycle test in −40° C. to 90° C., and a heat resistance test. On the other hand, when the gel fraction is equal to or smaller than the upper limit value, the solar-cell encapsulating material becomes highly flexible, and the temperature followability in a heat cycle test in −40° C. to 90° C. improves, and thus the occurrence of peeling can be prevented.

(Power Generation Facility)

The solar cell module of the embodiment is excellent in productivity, power generation efficiency, service life, and the like. Thus, a power generation facility in which the above-described solar cell module is used is excellent in costs, power generation efficiency, service life, and the like and has a high practical value. The power generation facility is preferable for long-term use regardless of indoor or outdoor use such as an outdoor-oriented mobile power supply for camping which is installed on the roof of a building and an auxiliary power supply in automobile batteries.

### EXAMPLE

The present invention will be specifically described below based on examples. However, the present invention is not limited to the following examples.

(1) Measuring Method

[Content Proportion of Ethylene Unit and α-olefin Unit]

0.35 g of a sample were heated and dissolved in 2.0 ml of hexachlorobutadiene, and thereby a solution was obtained. The obtained solution is filtered by a glass filter (G2). Then, 0.5 ml of deuterated benzene was added to the resultant of filtering. The resultant of addition was put into a NMR tube having an inner diameter of 10 mm. ¹³C-NMR was performed at 120° C. by using JNM GX-400 type NMR measuring device (manufactured by Jeol Ltd.). The accumulated number of times of measuring was equal to or greater than 8000 times. The content proportion of the ethylene unit, and the content proportion of the α-olefin unit in a copolymer were determined by using the obtained ¹³C-NMR spectrum.

[MFR]

The MFR of the ethylene•α-olefin copolymer was measured under conditions of a temperature of 190° C., and a load of 2.16 kg, based on ASTM D1238.

[Density]

The density of the ethylene•α-olefin copolymer was measured based on ASTM D1505.

[Shore A hardness]

After the ethylene•α-olefin copolymer was heated at 190° C. for four minutes and pressurized at 10 MPa, the ethylene•α-olefin copolymer was pressurized and cooled at 10 MPa to room temperature for five minutes, thereby a 3 mm-thick sheet was obtained. The Shore A hardness of the ethylene•α-olefin copolymer was measured on the basis of ASTM D2240 by using the obtained sheet.

[Content of Aluminum Element]

After the ethylene•α-olefin copolymer was wet-decomposed, the volume was made to be constant by using pure water, the amount of aluminum was determined by using an ICP emission spectrometer (ICPS-8100 manufactured by Shimadzu Corporation), and the content of the aluminum element was obtained.

(2) Manufacturing of Solar-Cell Encapsulating Material (Sheet)

### Example 1

0.5 parts by mass of γ-methacryloxypropyl trimethoxysilane as the silane coupling agent, 1.0 part by mass of t-butyl peroxy-2-ethylhexyl carbonate having a one-minute half-life temperature of 166° C. as the organic peroxide, 1.2 parts by mass of triallyl isocyanurate as the cross-linking assistant, 0.4 parts by mass of 2-hydroxy-4-normal-octyloxy benzophenone as the ultraviolet absorbing agent, 0.2 parts by mass of bis(2,2,6,6-tetramethyl-4-piperidyl)sebacate as the light stabilizer, 0.1 part by mass of tris(2,4-di-tert-butylphenyl)phosphite as the heat-resistance stabilizer 1, and 0.1 part by mass of octadecyl-3-(3,5-di-tert-butyl-4-hydroxyphenyl)propionate as the heat-resistance stabilizer 2 were blended into 100 parts by mass of an ethylene•α-olefin copolymer (α-olefin: 1-butene, density: 0.870 g/cm³, MFR: 20 g/10 minutes, a content proportion of a structural unit derived from ethylene: 86 mol %, a ratio of a structural unit derived from an α-olefin: 14 mol %, a Shore A hardness: 70, a content of an aluminum element: 102 ppm, were synthesized on the basis of Synthesis Example 1 described in Paragraph “0178” of WO2012-046456).

A coat-hanger type T dice (lip shape: 270×0.8 mm) was mounted in a single-axis extruder (diameter of screw of 20 mmφ, L/D=28) which is manufactured by Thermo Plastics Corporation. Molding was performed by using an embossing roll as a first cooling roll, and was performed at a roll temperature of 30° C., at a winding rate of 1.0 m/min under a condition of a dice temperature of 100° C. Thus, a sheet (solar-cell encapsulating material sheet) having a thickness of 500 μm was obtained.

A small module in which a single crystalline cell was used and one cell was included was produced by using the obtained solar-cell encapsulating material sheet and was evaluated. A white float glass plate (a thermal-treated glass having a thickness of 3.2 mm and including embosses) manufactured by AGC Fabritech Co., Ltd. cut into 24 cm×21 cm was used as the glass. As an n-type crystalline silicon-based solar cell element (n-type single crystal cell manufactured by Topsky Elecronics Technology (HK) Co., Ltd.), a cell which had a light-receiving surface side busbar silver electrode in the center and was cut into 5 cm×3 cm was used. A PET-based back sheet including silica-deposited PET was used as the back sheet, an approximately 2 cm-long cut was made in a part of the back sheet by using a cutter knife as an extraction portion from the cell, and a positive terminal and a negative terminal of the cell were extracted, and the components were laminated by using a vacuum laminator (LM-110×160-S manufactured by Seiko NPC Corporation) under conditions of a hot plate temperature of 150° C., a vacuum time of three minutes and a pressurization time of 15 minutes. After that, the encapsulating material and the back sheet protruded from the glass plate were cut, an end surface encapsulating material was supplied to the glass edge, thereby allowing attachment of an aluminum frame, and RTV silicone was supplied and cured at the cut portions of the terminal portion extracted from the back sheet.

The positive terminals and the negative terminals of the mini modules were short-circuited, and a high voltage side cable of a power supply was connected. In addition, a low voltage side cable of the power supply was connected to the aluminum frame, and the aluminum frame was grounded. The modules were set in a constant temperature and humidity tank at 85° C. and 85% rh, the temperature was increased, and then the modules were held under the application of −1,000 V.

As a high-voltage power supply, HARb-3R10-LF manufactured by Matsusada Precision Inc. was used, and, as a constant temperature and humidity tank, FS-214C2 manufactured by ETAC Engineering Co., Ltd. was used.

After a voltage was applied for 24 hours, the IV characteristics of this module were evaluated by using a xenon light source having a light intensity distribution of air mass (AM) 1.5 class A. In the IV evaluation, PVS-116i-S manufactured by Nisshinbo Mechatronics Inc. was used.

As a result of the measurement, in all of the cases, the maximum output power Pmax after the high-voltage test and the parallel resistance dark Rsh in dark measurement were almost the same as those in the initial phase, and no decreases were observed.

This application is based upon and claims the benefit of priority from Japanese Patent Application No. 2014-241319; filed on Nov. 28, 2014; the entire contents of which are incorporated herein by reference.

1. A solar cell module comprising:
an n-type crystalline silicon-based solar cell element as a power generation element,
wherein at least one surface of the n-type crystalline silicon-based solar cell element is encapsulated with a solar-cell encapsulating material including an ethylene•α-olefin copolymer satisfying the following requirements a1) to a4):
a1) A content proportion of a structural unit derived from ethylene is in a range of 80 to 90 mol %, and a content proportion of a structural unit derived from an α-olefin having 3 to 20 carbon atoms is in a range of 10 to 20 mol %,
a2) MFR, which is on the basis of ASTM D1238 and is measured under conditions of 190° C. and a load of 2.16 kg, is in a range of 0.1 to 50 g/10 minutes,
a3) A density, which is measured on the basis of ASTM D1505, is in a range of 0.865 to 0.884 g/cm³, and
a4) A Shore A hardness, which is measured on the basis of ASTM D2240, is in a range of 60 to 85.

2. The solar cell module according to claim 1,
wherein the solar-cell encapsulating material further satisfies the following requirement a5):
a5) A volume intrinsic resistance, which is on the basis of JIS K6911 and is measured at a temperature of 100° C. and an applied voltage of 500 V, is in a range of 1.0×10¹³ to 1.0×10¹⁸ Ω·cm.

3. The solar cell module according to claim 1,
wherein the ethylene•α-olefin copolymer further satisfies the following requirement a6):
a6) A content of an aluminum element in the ethylene•α-olefin copolymer is 10 to 500 ppm.

4. The solar cell module according to claim 2,
wherein the ethylene•α-olefin copolymer further satisfies the following requirement a6):
a6) A content of an aluminum element in the ethylene•α-olefin copolymer is 10 to 500 ppm.

5. The solar cell module according to claim 1,
wherein the MFR of the ethylene •α-olefin copolymer which is on the basis of ASTM D1238 and is measured under conditions of 190° C. and a load of 2.16 kg is 2 to 27 g/10 minutes.

6. The solar cell module according to claim 1,
wherein the solar-cell encapsulating material further includes 0.005 to 5.0 parts by mass of an organic peroxide having a one-minute half-life temperature in a range of 100° C. to 170° C. with respect to 100 parts by mass of the ethylene•α-olefin copolymer.

7. The solar cell module according to claim 1,
wherein the ethylene•α-olefin copolymer is a copolymer polymerized in the presence of a catalyst for olefin polymerization which is made up of a metallocene compound and at least one type of compound selected from the group consisting of organic aluminum oxy compounds and organic aluminum compounds.

8. The solar cell module according to claim 1,
wherein the solar-cell encapsulating material is made of an ethylene-based resin composition including 0.1 to 5 parts by mass of a silane coupling agent and 0.1 to 3 parts by mass of a cross-linking agent with respect to 100 parts by mass of the ethylene•α-olefin copolymer.

9. The solar cell module according to claim 8,
wherein the ethylene-based resin composition included in the solar-cell encapsulating material further includes 0.005 to 5 parts by mass of at least one type selected from the group consisting of an ultraviolet absorbing agent, a heat-resistance stabilizer, and a light stabilizer with respect to 100 parts by mass of the ethylene•α-olefin copolymer.

10. The solar cell module according to claim 8,
wherein the ethylene-based resin composition included in the solar-cell encapsulating material further includes 0.05 to 5 parts by mass of a cross-linking assistant with respect to 100 parts by mass of the ethylene•α-olefin copolymer.

11. The solar cell module according to claim 1,
wherein the solar-cell encapsulating material is a material obtained by dissolving and kneading the ethylene•α-olefin copolymer and an additive and then extruding the ethylene•α-olefin copolymer and the additive in a sheet shape.

12. The solar cell module according to claim 1,
wherein the solar-cell encapsulating material has a sheet shape.

13. The solar cell module according to claim 1, further comprising:
a front surface side transparent protection member;
a back surface side protection member; and
an encapsulating layer which is formed by cross-linking the solar-cell encapsulating material and encapsulates the n-type crystalline silicon-based solar cell element between the front surface side transparent protection member and the back surface side protection member.
